(19) United States
(12) Patent Application Publication
(10) Pub. No.: US 2015/0092805 A1
(43) Pub. Date: Apr. 2, 2015

(54) SEMICONDUCTOR LASER DEVICE

(71) Applicant: Mitsubishi Electric Corporation, Tokyo (JP)

(72) Inventor: Hiroshi Mitsuyama, Tokyo (JP)

(21) Appl. No.: 14/315,395

(22) Filed: Jun. 26, 2014

(30) Foreign Application Priority Data
Oct. 1, 2013 (JP) 2013-206549

(51) Int. Cl. H01S 5/026

(52) U.S. Cl. CPC H01S 5/0261
USPC 372/38.09

(57) ABSTRACT

A semiconductor laser device includes a semiconductor laser element having an active layer and semiconductor layers on opposite sides of the active layer, and a PN-junction diode in part of the semiconductor layers. The PN-junction diode is connected, in inverse polarity, in parallel with the semiconductor laser element.

### BACKGROUND OF THE INVENTION

1. Field of the Invention

The present invention relates to a semiconductor laser device used as a sensor such as a scanner, means for readout from and recording on a compact disk (CD), a digital versatile disk (DVD), a Blue-ray disk (BD) medium, or the like, means for optical communication, means for laser machining, or means for display such as a projector or a TV backlight.

2. Background Art

There is a possibility of a semiconductor laser element being deteriorated, for example, by excessive emission of light, damage to an insulating layer or damage to a PN-junction when a surge voltage is applied to the semiconductor laser element by static electricity, overshoot in power supply, or the like. Japanese Patent Laid-Open No. 59-178784 discloses a technique for limiting deterioration of a semiconductor laser element caused by a surge voltage. This technique resides in providing on the semiconductor laser element a diode that functions as a circuit for protection of the semiconductor laser element.

It is preferred that a semiconductor laser device having a semiconductor laser element and a portion for protecting the semiconductor laser device from a surge voltage should be provided while being minimized in size. The semiconductor laser device disclosed in Japanese Patent Laid-Open No. 59-178784 has the semiconductor laser element and the diode provided as separate parts and therefore has a problem that it cannot be reduced in size.

### SUMMARY OF THE INVENTION

The present invention has been made to solve the above-described problem, and an object of the present invention is to provide a semiconductor laser device suited for size-reduction.

The features and advantages of the present invention may be summarized as follows.

According to one aspect of the present invention, a semiconductor laser device includes a semiconductor laser element having an active layer and a plurality of semiconductor layers formed on opposite sides of the active layer, and a PN junction diode formed in part of the plurality of semiconductor layers. The PN-junction diode is connected in inverse parallel with the semiconductor laser element.

According to another aspect of the present invention, a semiconductor laser device includes a sub mount having an insulating member and a surface metal layer formed on the insulating member, a semiconductor laser element having an upper surface electrode and a lower surface electrode, the lower surface electrode being connected to the surface metal layer, a capacitor having a first electrode and a second electrode and provided on the semiconductor laser element, and a wire connecting the first electrode and the surface metal layer to each other. The second electrode is connected to the upper surface electrode.

According to another aspect of the present invention, a semiconductor laser device includes a metal plate, a sub mount having a dielectric, a first metal and a second metal formed on the upper surface side of the dielectric, and a third metal formed on the lower surface side of the dielectric and adjoining the metal plate, a semiconductor laser element having an upper surface electrode and a lower surface electrode, the lower surface electrode being connected to the first metal, a first wire connecting the upper surface electrode and the second metal to each other, and a second wire connecting the first metal and the metal plate to each other.

Other and further objects, features and advantages of the invention will appear more fully from the following description.

### BRIEF DESCRIPTION OF THE DRAWINGS

FIG. 1 is a sectional view of a semiconductor laser device according to the first embodiment;

FIG. 2 is an equivalent circuit diagram of the semiconductor laser device shown in FIG. 1;

FIG. 3 is a sectional view of a semiconductor laser device according to a modified example of the first embodiment;

FIG. 4 is a sectional view of a semiconductor laser device according to the second embodiment of the present invention;

FIG. 5 is an equivalent circuit diagram of the semiconductor laser device shown in FIG. 4;

FIG. 6 is a sectional view of a semiconductor laser device according to the third embodiment;

FIG. 7 shows a semiconductor laser device equivalent in function to the semiconductor laser device shown in FIG. 6; and

FIG. 8 is a sectional view of a semiconductor laser device according to the fourth embodiment.

### DETAILED DESCRIPTION OF THE PREFERRED EMBODIMENTS

Semiconductor laser devices according to embodiments of the present invention will be described with reference to the accompanying drawings. Components identical or corresponding to each other are indicated by the same reference characters, and the description of them will be made by removing some redundancies therein.

### First Embodiment

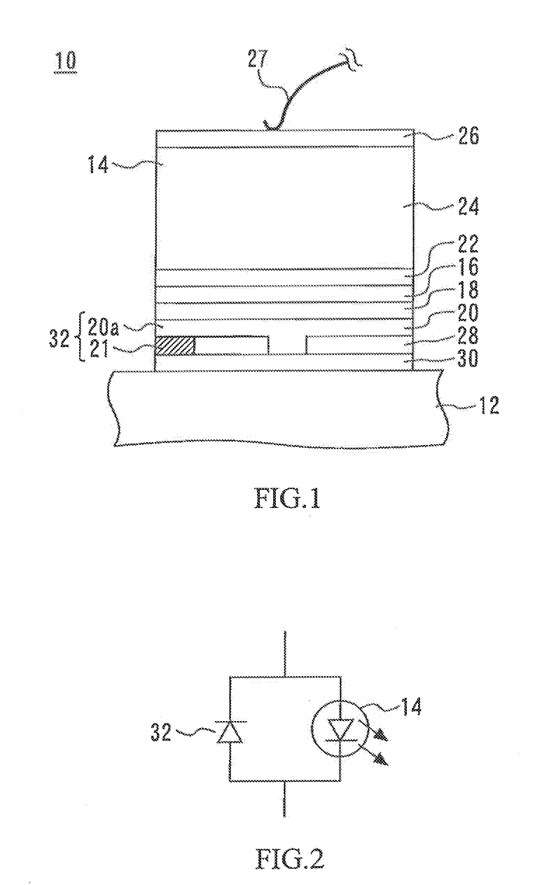

FIG. 1 is a sectional view of a semiconductor laser device 10 according to the first embodiment of the present invention. The semiconductor laser device 10 has a sub mount 12 and a semiconductor laser element 14 formed on the sub mount 12. The semiconductor laser element 14 has an active layer 16. A p-type cladding layer 18 is formed on the lower surface side of the active layer 16. A p-type cap layer 20 is formed on the lower surface side of the p-type cladding layer 18.

An n-type cap layer 21 is formed on the lower surface side of the p-type cap layer 20 so as to adjoin part of the p-type cap layer 20. The p-type cap layer 20 and the n-type cap layer 21 are formed, for example, as described below. The region where p-type cap layer 20 and the n-type cap layer 21 are to be formed is implanted with a p-type impurity, and the portion to be formed as the n-type cap layer 21 is thereafter implanted with an n-type impurity. Thus, the n-type cap layer 21 can be easily formed at a low cost by an existing impurity diffusion process.

An n-type cladding layer 22 is formed on the upper surface side of the active layer 16 shown in FIG. 1. An n-type substrate 24 is provided on the upper surface side of the n-type cladding layer 22. As described above, the plurality of semiconductor layers (p-type cladding layer 18, p-type cap layer 20, n-type cap layer 21, n-type cladding layer 22, and n-type substrate 24) are formed on the opposite sides of the active layer 16.

An upper surface electrode 26 is formed on the upper surface side of the n-type substrate 24. A wire 27 is fixed to the upper surface electrode 26. An insulating layer 28 having an opening is formed on the lower surface side of the p-type cap layer 20. A lower surface electrode 30 is formed so as to adjoin the lower surface of the p-type cap layer 20 exposed from the opening, the lower surface of the insulating layer 28 and the lower surface of the n-type cap layer 21.

A PN-junction diode 32 is formed in part of the above-described plurality of semiconductor layers. The PN-junction diode 32 is formed by a portion 20a of the p-type cap layer 20 and the n-type cap layer 21. The PN-junction diode 32 is connected in inverse parallel with the semiconductor laser element 14. “Inverse parallel” signifies that two elements are connected in parallel with each other while the conducting directions of the two elements are opposite to each other.

FIG. 2 is an equivalent circuit diagram of the semiconductor laser device 10 shown in FIG. 1. The semiconductor laser element 14 and the PN-junction diode 32 are connected in inverse parallel with each other. A case where a forward surge voltage is applied to the semiconductor laser element 14 will be described. When a forward surge voltage is applied to the semiconductor laser element 14, a reverse voltage equal to or higher than a certain value is applied to the PN junction diode 32 to cause avalanche breakdown in the PN-junction diode 32. A surge current is thereby caused to flow through the PN-junction diode 32, thus enabling prevention of deterioration of the semiconductor laser element 14 caused by flowing of an excessively large current through the semiconductor laser element 14.

In the case where the PN junction diode is connected “in parallel” with the semiconductor laser diode, the forward ON voltage on the semiconductor laser element causes an unignorable current to flow through the PN-junction diode, thereby affecting the operation of the semiconductor laser element. In the case where the PN-junction diode 32 is connected in inverse parallel with the semiconductor laser element 14, the current caused by the forward ON voltage on the semiconductor laser element 14 to flow through the PN-junction diode 32 is negligibly small, thus avoiding affecting the operation of the semiconductor laser element.

The voltage at which avalanche breakdown in the PN-junction diode 32 occurs can be controlled by adjusting the impurity concentration in the n-type cap layer 21. For example, deterioration of the semiconductor laser element 14 by a low forward surge voltage can be prevented by reducing the difference between the voltage at which avalanche breakdown occurs and the forward ON voltage on the semiconductor laser element 14.

A case where a reverse surge voltage is applied to the semiconductor laser element 14 will next be described. When a reverse surge voltage is applied to the semiconductor laser element 14, a forward voltage is applied to the PN-junction diode 32 to turn on the PN-junction diode 32. Thus, by causing the surge voltage flowing through the PN-junction diode 32, it enables prevention of deterioration of the semiconductor laser element 14 caused by flowing of an excessively large current through the semiconductor laser element 14.

Thus, deterioration of the semiconductor laser element 14 can be prevented by bypassing through the PN-junction diode 32 each of excessively large currents caused by a forward surge voltage and a reverse surge voltage on the semiconductor laser element 14. Moreover, since the PN-junction diode 32 is formed in part of the plurality of semiconductor layers, the semiconductor laser device 10 is suited to a size-reduction design. Also, since the PN-junction diode 32 can be formed by only changing part of the existing process, the semiconductor laser device 10 can be manufactured at a low cost.

The semiconductor layers constituting the above-described plurality of layers are not limited to those described above. For example, the plurality of semiconductor layers may include an optical guide layer. Only forming the PN-junction diode in part of the plurality of semiconductor layers suffices. It is not necessarily required that the PN-junction diode use the p-type cap layer 20. The structure of the semiconductor laser element 14 is not restrictively specified. For example, the semiconductor laser element 14 may be of a ridge type or a buried type. The method of driving the semiconductor laser element 14 may be a continuous wave (CW) drive method or a pulse drive method.

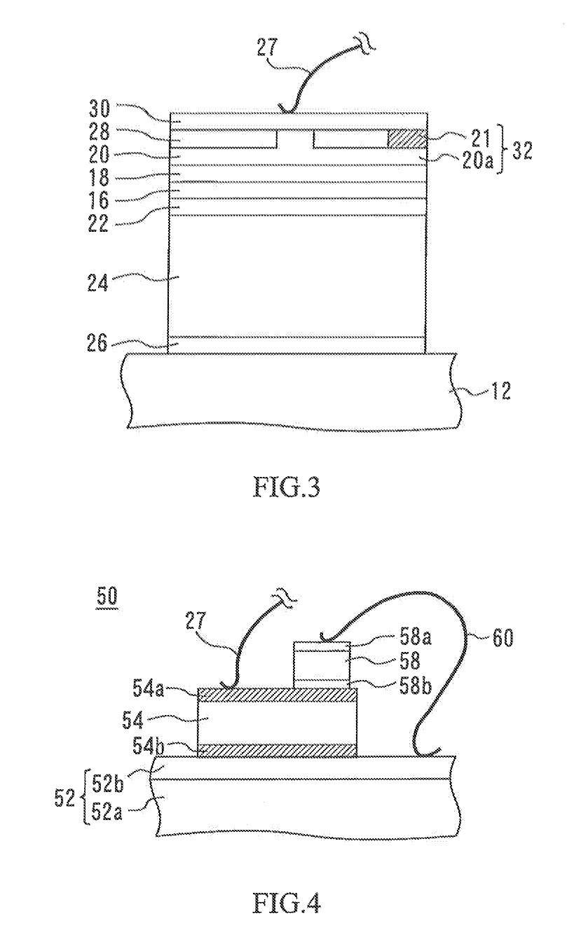

FIG. 3 is a sectional view of a semiconductor laser device according to a modified example of the first embodiment. This semiconductor laser device has a semiconductor laser element which has the same configuration as that of the semiconductor laser element 14 shown in FIG. 1, but the semiconductor laser element of this semiconductor laser device is inverted relative to the semiconductor laser element 14 shown in FIG. 1 and fixed on the sub mount 12. The semiconductor laser device shown in FIG. 3 is equivalent in function to the semiconductor laser device 10 shown in FIG. 1. These modifications can also be applied to semiconductor laser devices according to the embodiments described below.

### Second Embodiment

FIG. 4 is a sectional view of a semiconductor laser device 50 according to the second embodiment of the present invention. The semiconductor laser device 50 has a sub mount 52. The sub mount 52 has an insulating member 52a and a surface metal layer 52b formed on the insulating member 52a. A semiconductor laser element 54 is provided on the sub mount 52. The semiconductor laser element 54 has an upper surface electrode 54a and a lower surface electrode 54b connected to the surface metal layer 52b.

A capacitor 58 is provided on the semiconductor laser element 54. The capacitor 58 has a first electrode 58a on its upper surface side and has a second electrode 58b on its lower surface side. The second electrode 58b is connected to the upper surface electrode 54a. The first electrode 58a and the surface metal layer 52b are connected to each other by a wire 60.

FIG. 5 is an equivalent circuit diagram of the semiconductor laser device 50 shown in FIG. 4. The capacitor 58 is connected in parallel with the semiconductor laser element 54. The capacitor 58 bypasses a surge current caused by a forward surge voltage or a reverse surge voltage on the semiconductor laser element 54, thus enabling prevention of flowing of an excessively large current through the semiconductor laser element 54. Further, through adjustment of the electrical capacity of the capacitor 58, only a current with a large time constant can be selected and applied to the semiconductor laser element 54. Therefore, pulse drive of the semiconductor laser element 54 can be performed as well as CW drive.

The semiconductor laser device 50 according to the second embodiment of the present invention has the capacitor 58 assembled on the top of the semiconductor laser element 54, so that the increase in external size of the semiconductor laser device 50 can be minimized. Thus, the semiconductor laser device 50 is suited to a size-reduction design. Also, the semiconductor laser element 54, the capacitor 58 and the sub mount 52 are collectively assembled in a package, so that the semiconductor laser device can be manufactured without increasing the number of manufacturing process steps.

### Third Embodiment

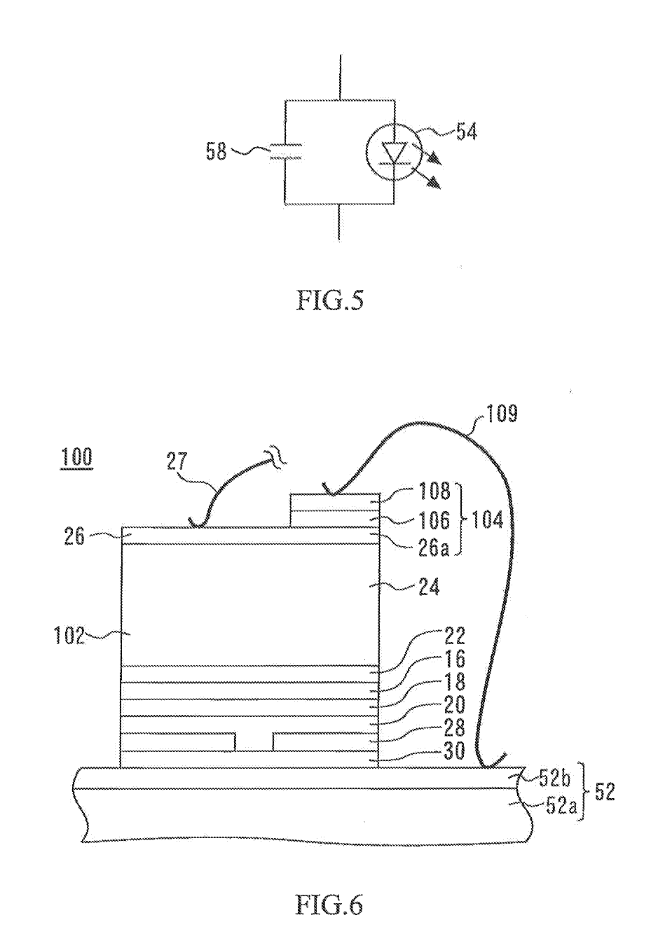

FIG. 6 is a sectional view of a semiconductor laser device 100 according to the third embodiment of the present invention. A semiconductor laser element 102 is provided on a sub mount 52. A capacitor 104 is formed on the semiconductor laser element 102. The capacitor 104 has an insulating layer 106 formed on a portion 26a of the upper surface electrode 26 and a first electrode 108 formed on the insulating layer 106. The portion 26a of the upper surface electrode 26 functions as a second electrode of the capacitor 104.

Thus, the capacitor 104 has a metal-insulator-metal (MIM) structure formed by the second electrode 26a, the insulating layer 106 and the first electrode 108. The capacitor 104 having the MIM structure can be formed at a low cost by using an existing vapor deposition, sputtering or chemical vapor deposition (CVD) process. The first electrode 108 and the surface metal layer 52b are connected to each other by a wire 109. The capacitor 104 is thereby connected in parallel with the semiconductor laser element 102.

The semiconductor laser device 100, the capacitor 104 can bypass an excessively large current caused by a forward surge voltage or a reverse surge voltage on the semiconductor laser element 102, thus enabling prevention of deterioration of the semiconductor laser element 102. Also, only a current with a large time constant can be selected and applied to the semiconductor laser element 102 by adjusting the thickness of the insulating layer 106 of the capacitor 104 or the size of the first electrode 108 and the second electrode 26a for example. Therefore, pulse drive of the semiconductor laser element 102 can be performed as well as CW drive. Assembly of the capacitor 104 on the top of the semiconductor laser element 102 enables making the semiconductor laser device suited to a size-reduction design minimizing the increase in external size.

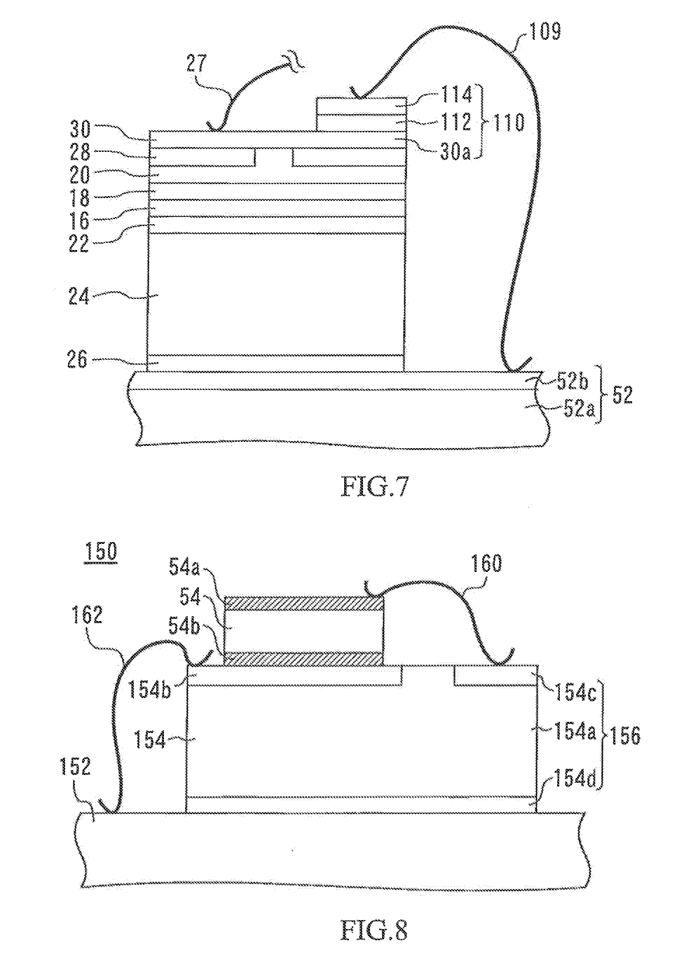

FIG. 7 is a sectional view of a semiconductor laser device according to a modified example of the third embodiment. This semiconductor laser device has a capacitor 110 that uses a portion 30a of the lower surface electrode 30 as its second electrode. The capacitor 110 has a second electrode 30a, an insulating layer 112 on the second electrode 30a, and a first electrode 114 on the insulating layer 112. The semiconductor laser device shown in FIG. 7 is equivalent in function to the semiconductor laser device 100 shown in FIG. 6.

### Fourth Embodiment

FIG. 8 is a sectional view of a semiconductor laser device 150 according to the fourth embodiment of the present invention. The semiconductor laser device 150 has a metal plate 152. A sub mount 154 is provided on the metal plate 152. The sub mount 154 has a dielectric 154a and first to third metals 154b, 154c, and 154d. The first metal 154b and the second metal 154c are formed on the upper surface side of the dielectric 154a. The third metal 154d is formed on the lower surface side of the dielectric 154a and adjoins the metal plate 152.

A semiconductor laser element 54 is provided on the sub mount 154. A lower surface electrode 54b of the semiconductor laser element 54 is connected to the first metal 154b. An upper surface electrode 54a of the semiconductor laser element 54 and the second metal 154c are connected to each other by a first wire 160. The first metal 154b and the metal plate 152 are connected to each other by a second wire 162.

Thus, the second metal 154c, the dielectric 154a and the third metal 154d of the sub mount 154 form a capacitor 156. The capacitor 156 is connected in parallel with the semiconductor laser element 54. The capacitor 156 can bypass an excessively large current caused by a forward surge voltage or a reverse surge voltage on the semiconductor laser element 54, thus enabling prevention of deterioration of the semiconductor laser element 54.

The electrical capacity of the capacitor 156 can easily be changed by changing the material or thickness of the dielectric 154a and the size (shape) of the second metal 154c. A current with a large time constant for example can thereby be applied to the semiconductor laser element 54. Therefore, pulse drive of the semiconductor laser element 54 can be performed as well as CW drive. Since the capacitor 156 is formed by a portion of the sub mount 154, the number of component parts is not increased by the provision of the capacitor 156, thus enabling the semiconductor laser device 150 to be manufactured at a low cost.

According to the present invention, the structure for protecting the semiconductor laser element from a surge voltage is provided in the semiconductor laser element or immediately above the semiconductor laser element or formed by using part of the semiconductor laser element. As a result, a semiconductor laser device suited to a size-reduction design can be provided.

Obviously many modifications and variations of the present invention are possible in the light of the above teachings. It is therefore to be understood that within the scope of the appended claims the invention may be practiced otherwise than as specifically described.

1. A semiconductor laser device comprising:
a semiconductor laser element having an active layer and a plurality of semiconductor layers located on opposite sides of the active layer; and
a PN-junction diode located in part of the plurality of semiconductor layers, wherein the PN-junction diode is connected, in inverse polarity, in parallel with the semiconductor laser element.

2. The semiconductor laser device according to claim 1, wherein the plurality of semiconductor layers includes:
a p-type cap layer; and
an n-type cap layer adjoining the p-type cap layer, whereby the p-type cap layer and the n-type cap layer form the PN-junction diode.

3. A semiconductor laser device comprising:
a sub mount having an insulating member and a surface metal layer on the insulating member;
a semiconductor laser element having an upper surface electrode and a lower surface electrode, the lower surface electrode being connected to the surface metal layer;
a capacitor having a first electrode and a second electrode and disposed on the semiconductor laser element; and
a wire connecting the first electrode and the surface metal layer to each other, whereby the second electrode is connected to the upper surface electrode.

4. The semiconductor laser device according to claim 3, wherein part of the upper surface electrode is the second electrode.

5. The semiconductor laser device according to claim 3, wherein the capacitor has a metal-insulator-metal (MIM) structure.

6. A semiconductor laser device comprising:
a metal plate;
a sub mount having a dielectric, a first metal and a second metal on an upper surface side of the dielectric, and a third metal located on a lower surface side of the dielectric and adjoining the metal plate;
a semiconductor laser element having an upper surface electrode and a lower surface electrode, the lower surface electrode being connected to the first metal;
a first wire connecting the upper surface electrode and the second metal to each other; and
a second wire connecting the first metal and the metal plate to each other.
